(19) United States
(12) Patent Application Publication
(10) Pub. No.: US 2008/0070017 A1
(43) Pub. Date: Mar. 20, 2008

(54) Layered Thin Film Structure, Layered Thin Film Forming Method, Film Forming System and Storage Medium

(76) Inventors: Naoki Yoshii, Yamanashi-ken (JP); Yasuhiko Kojima, Yamanashi-Ken (JP); Hiroshi Sato, Yamanashi-Ken (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 11/884,020

(22) PCT Filed: Jan. 30, 2006
(86) PCT No.: PCT/JP06/01459

§ 371 Date: Aug. 9, 2007

(30) Foreign Application Priority Data
Feb. 10, 2005 (JP) 2005-035299

(51) Int. Cl. H01L 21/44; B32B 7/02; C23C 16/00

(52) U.S. Cl. 428/216; 118/728; 428/213; 438/656; 257/E21.476

(57) ABSTRACT

There is provided a layered thin film structure forming method capable of forming a layered thin film structure bonded to an underlying layer by high adhesion, of suppressing the peeling of the layered thin film structure off the underlying layer, of achieving satisfactory step coverage even under high miniaturization, and of satisfactorily diffusing an alloying element.

A layered thin film structure forming method of forming a layered thin film structure by depositing a plurality of thin films on a surface of a workpiece in a processing vessel capable of being evacuated includes the steps of: forming an alloying-element film 104 of a first metal by using a source gas containing the first metal as an alloying element, and a reducing gas; and forming a base-metal film 106 of a second metal in a thickness greater than that of the alloying-element film by using a source gas containing the second metal, and a reducing gas. At least one cycle of the alternate steps of forming the alloying-element film and forming the base-metal film is executed.

### TECHNICAL FIELD

The present invention relates to a layered thin film structure to be formed on a surface of a substrate, such as a semiconductor wafer, a layered thin film structure forming method of forming the same, a film forming system for carrying out the layered thin film structure forming method, and a storage medium storing a program for controlling the film forming system.

### BACKGROUND ART

Generally, a workpiece, such as a semiconductor wafer, is subjected repeatedly to processes including a film forming process, an etching process, an oxidation and diffusion process, an annealing process and a modification process to form a semiconductor integrated circuit, such as an IC or a LSI, on the substrate. Thickness of wiring layers and the width of lines have been progressively reduced to meet demand for further increasing the scale of integration, further device miniaturization and further increase in operating speed. Use of copper wiring lines having low resistance lower than that of aluminum wiring lines has been proposed to meet the foregoing recent condition (Patent document 1). Generally, copper wiring lines are formed by forming a copper film on a surface of a wafer or the like by a sputtering system and removing unnecessary parts of the copper film to form a desired wiring pattern.

Copper wiring lines, unlike aluminum wiring lines, are very likely to cause electromigration or stress-migration in boundaries between the wiring lines and other material, such as silicon. Consequently, the adhesion bonding copper wiring lines and the underlying layer together is reduced and copper wiring lines are liable to come off the underlying layer. The reduction of the adhesion bonding together the copper wiring lines and the underlying layer has become an unignorable, significant problem with the progress of device miniaturization.

To suppress migration, there is a proposal to form a wiring pattern of a copper alloy containing an alloying metal, such as Ti or Al, in a small content, such as a content on the order of 1%. A copper alloy thin film is formed on a surface of a wafer by, for example, a plasma sputtering process using a copper alloy target containing a desired alloying element, such as Ti, in a content on the order of several percents.

Patent document 1: JP 2000-77365 A

### DISCLOSURE OF THE INVENTION

Although the copper alloy film is formed by a sputtering process, the formation of a film by a sputtering process has difficulty in satisfying step coverage required by current design rules specifying fine wiring lines and cannot satisfactorily filling up recesses in the surface of a wafer.

Even if it is desired that desired parts of a deposited copper alloy film, such as boundary parts of the copper alloy film continuous with the underlying layer, have an alloying element content higher than those of other parts of the copper alloy film, the alloying element content of the copper alloy film is dependent on the alloying element content of a previously prepared metal target and the alloying element content cannot be changed during the sputtering process for forming the copper alloy film. Therefore, it has been impossible to control the alloying element content of a copper alloy film such that specific parts of the copper alloy film have, for example, a high alloying element content. Therefore, migration cannot be satisfactorily suppressed. Consequently, the copper alloy film and the underlying layer could not have been bonded together by sufficiently high adhesion and, in some cases, peeling off of the copper alloy film from the underlying layer could not have been prevented.

A CVD process (chemical vapor deposition process) may be used instead of the sputtering process to form the copper alloy film. However, a CVD process can form only a metal film of a single kind at a time and a simple application of a CVD process cannot evenly mix or disperse atoms of an alloying element in a film.

The present invention has been made in view of those problems to solve those problems effectively and it is therefore an object of the present invention to provide a layered thin film structure including a thin film and an underlying layer bonded together by high adhesion and resistant to peeling, capable of ensuring high coverage under high miniaturization, and capable of satisfactorily dispersing an alloying element in a film.

### MEANS FOR SOLVING THE PROBLEM

A layered thin film structure forming method of forming a layered thin film structure by depositing a plurality of thin films on a surface of a workpiece in a processing vessel capable of being evacuated in a first aspect of the present invention includes the steps of: forming an alloying-element film of a first metal by using a source gas containing the first metal as an alloying element, and a reducing gas; and forming a base-metal film of a second metal different from the first metal in a thickness greater than that of the alloying-element film by using a source gas containing the second metal, and a reducing gas; wherein at least one cycle of the alternate steps of forming the alloying-element film and forming the base-metal film is executed.

An alloy layer is formed by executing at least one cycle of the alternate steps of forming the alloying-element film and forming the base-metal film. Therefore, the alloy layer can be bonded to the underlying layer by high adhesion, the peeling of the alloy layer off the underlying layer can be suppressed, satisfactory step coverage can be achieved even under high miniaturization, and the alloying element can be satisfactorily diffused.

Preferably, an intermittent film forming process in which the source gas containing the first metal, and the reducing gas are supplied alternately and intermittently in different periods, respectively, into the processing vessel or a continuous film forming process in which the source gas containing the first metal, and the reducing gas are supplied simultaneously into the processing vessel is carried out in the step of forming the alloying-element film.

Preferably, an intermittent film forming process in which the source gas containing the second metal, and the reducing gas are supplied alternately and intermittently in different periods, respectively, into the processing vessel or a continuous film forming process in which the source gas containing the second metal, and the reducing gas are supplied simultaneously into the processing vessel is carried out in the step of forming the base-metal film.

Preferably, the workpiece is subjected to an annealing process for heating the workpiece at a predetermined temperature after completing one cycle of the alternate steps of forming an alloying-element film of a first metal and forming a base-metal film of a second metal.

Preferably, the step of forming an alloying-element film and the step of forming a base-metal film are executed in the same processing vessel.

Preferably, the step of forming an alloying-element film and the step of forming a base-metal film are executed alternately in different processing vessels, respectively.

The alloying-element film has a thickness between 1 and 200 Å, and the base-metal film has a thickness between 5 and 500 Å.

Preferably, the first metal is one of a group of metals including Ti, Sn, W, Ta, Mg, In, Al, Ag, Co, Nb, B, V and Mn.

Preferably, the second metal is one of a group of metals including Cu, Ag, Au and W.

Preferably, the reducing gas is one or a mixture of some of H₂, NH₃, N₂, N₂H₄ (hydrazine), NH(CH₃)₂ (ethylamine), N₂H₃CH (methyl diazine) or N₂H₃CH₃ (methyl hydrazine).

A layered thin film structure formed on a surface of a workpiece in a second aspect of the present invention includes at least one alloying-element film of a first metal formed by using a source gas containing the first metal as an alloying element, and a reducing gas; and at least one base-metal film of a second metal having a thickness greater than that of the alloying-element film formed by using a source gas containing the second metal different form the first metal, and a reducing gas; wherein the alloying-element film and the base-metal film are formed in alternate layers.

Preferably, the alloying-element film has a thickness between 1 and 200 Å, and the base-metal film has a thickness between 5 and 500 Å.

A film forming system for depositing thin films on a surface of a workpiece in a third aspect of the present invention includes: a processing vessel capable of being evacuated; a stage supporting the workpiece thereon; a heating means for heating the workpiece; a gas introducing means for introducing gases into the processing vessel; a first source gas supply means for supplying a source gas containing a first metal as an alloying element to the gas introducing means; a second gas supply means for supplying a source gas containing a second metal as a base material to the gas introducing means; a reducing gas supply means for supplying a reducing gas to the gas introducing means; and a control means for controlling film forming operations such that at least one alloying-element film of the first metal and at least one base-metal film of the second metal are formed in alternate layers.

Preferably, the film forming system further includes a plasma generating means for generating a plasma in the processing vessel.

A storage medium in a fourth aspect of the present invention stores a program for controlling a film forming system for forming a layered thin film structure by depositing a plurality of thin films on a surface of a workpiece in a processing vessel capable of being evacuated such that the film forming system executes at least one cycle of alternate steps of forming an alloying-element film of a first metal by using a source gas containing the first metal as an alloying element and, a reducing gas, and forming a base-metal film of a second metal in a thickness greater than that of the alloying-element film by using a source gas containing the second metal, and a reducing gas.

### EFFECT OF THE INVENTION

The layered thin film structure, the layered thin film structure forming method of forming the same, the film forming system and the storage medium according to the present invention exercise the following effects.

Since the alloy layer is formed by executing at least one cycle of the alternate steps of forming the alloying-element film of the first metal as the alloying metal and forming the base-metal film of the second metal, the alloy layer can be bonded to the underlying layer by high adhesion, the peeling of the alloy layer off the underlying layer can be suppressed, satisfactory step coverage can be achieved even under high miniaturization, and the alloying element can be satisfactorily diffused.

### BRIEF DESCRIPTION OF THE DRAWINGS

FIG. 1 is a block diagram of a film forming system in a preferred embodiment according to the present invention.

FIG. 2 is a flow chart of a layered thin film forming method according to the present invention.

FIG. 3 is a sectional view showing a layered thin film structure by way of example.

FIG. 4 is a time chart showing timing the supply of gases.

FIG. 5 is a profile diagram showing respective distributions of Ti content and Cu content of a surface of a wafer.

FIG. 6 is a time chart showing timing the supply of gases to form a layered thin film structure by a plasma CVD process.

### BEST MODE FOR CARRYING OUT THE INVENTION

A layered thin film structure, a layered thin film structure forming method of forming the same, a film forming system and a storage medium in preferred embodiments according to the present invention will be described with reference to the accompanying drawings.

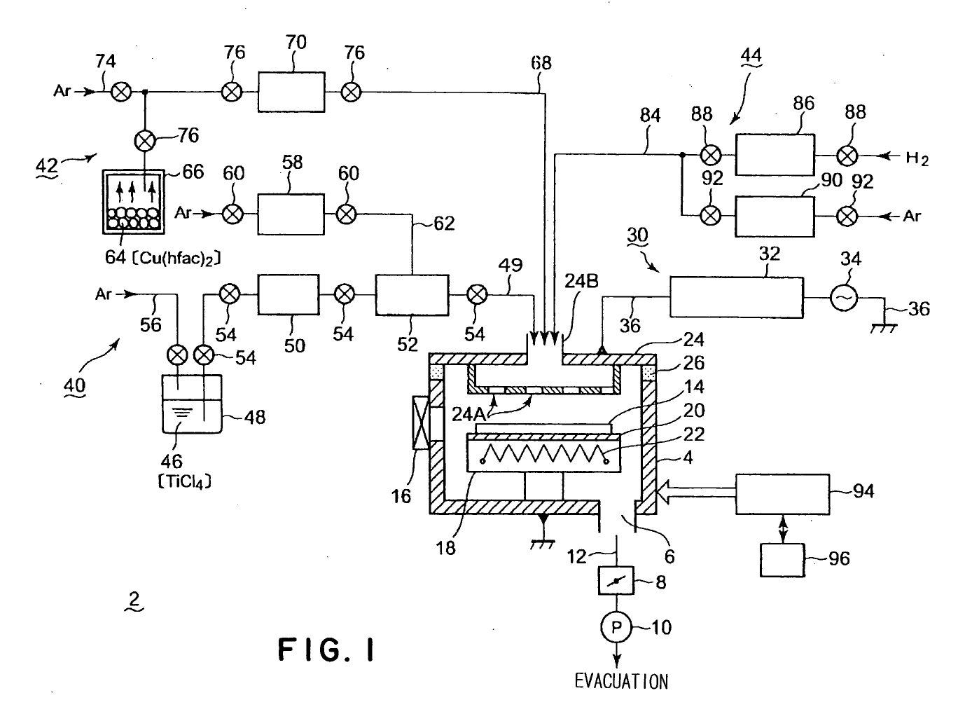

FIG. 1 is a block diagram of a film forming system in a preferred embodiment according to the present invention.

The film forming system of the present invention will be described. The film forming system 2 has a cylindrical processing vessel 4 of, for example, aluminum. The processing vessel 4 is grounded. The processing vessel 4 has a bottom wall provided with an exhaust port 6. An evacuating system 12 including a pressure regulating valve 8 and a vacuum pump 10 is connected to the exhaust port 6. The evacuating system 12 evacuates the processing vessel 4 at a desired pressure.

A gate valve 16 is attached to the side wall of the processing vessel 4. The gate valve 16 is opened to carry a semiconductor wafer 14, namely, a workpiece, in and to carry out the semiconductor wafer 14 from the processing vessel. A stage 18, which is used also as a lower electrode, is disposed in the processing vessel 4 and is mounted on a support set upright on the bottom surface of the processing vessel 4. For example, a thin electrostatic chuck 20 is mounted on the upper surface of the stage 18. The electrostatic chuck 20 attracts and holds the wafer 14 by electrostatic force. The electrostatic chuck 20 is capable of transmitting high-frequency waves and serves as a lower electrode. The stage 18 is internally provided with a heating means 22 including a heater, for heating the wafer W at a predetermined temperature. The heating means 22 may include a heating lamp instead of the heater.

For example, a shower head 24 as a gas introducing means is attached to the upper end of the processing vessel 4. The shower head 24 is insulated from the processing vessel 4 by an insulating member 26. Necessary gases are introduced into the processing vessel 4 through the shower head 24. Many spouting pores 24A are formed in the lower wall of the shower head 24, and a gas inlet port 24B is formed in the upper wall of the shower head 24. Necessary gases are spouted through the spouting pores 24A into the processing vessel 4. Only the single gas inlet port 24B is shown in FIG. 1. Actually, the shower head 24 is provided with a plurality of gas inlet ports respectively for different gases. The supplied gases are mixed in the shower head 24 when the gases supplied respectively through the gas supply ports may be mixed in the shower head 24. The supplied gases flow separately in the shower head 24 and are mixed after being spouted through the spouting pores 24A when the gases should not be mixed in the shower head 24.

The shower head 24 is connected to a plasma generating means 30. The shower head 24 serves also as an upper electrode opposed to the stage 18 serving as the lower electrode and disposed below the shower head 24. More concretely, the plasma generating means 30 is formed by successively connecting a matching circuit 32 and a high-frequency power supply 34 to a power feed line 36. The power feed line 36 is connected to the shower head 24. A plasma is generated in the processing vessel 4 by the agency of a high-frequency wave. A power supply capable of generating a high-frequency wave of, for example, 13.56 MHz is used as the high-frequency power supply 34. The frequency of the high-frequency wave is not limited to 13.56 MHz.

A first source gas supply means 40 for supplying a source gas containing a first metal as an alloying element, a second source gas supply means 42 for supplying a source gas containing a second metal as a base material, and a reducing gas supply means 44 for supplying a reducing gas are connected to the shower head 24. The source gases are produced by gasifying liquid or solid materials. There are not particular restrictions on the method of producing the source gases; the source gases may be may be supplied from gas cylinders.

The first source gas supply means 40 has a source material tank 48 containing a liquid material 46 containing the first metal as an alloying element. The first metal is Ti, and the liquid material 46 is TiCl₄ (titanium tetrachloride). The source material tank 48 is connected to the gas inlet port 24B of the shower head 24 by a source material supply line 49. A liquid flow controller 50 and a vaporizer 52 are placed in that order in the source material supply line 49 from the upstream side toward the downstream side of the source material supply line 49. Thus the flow of the liquid material 46 through the source material supply line 49 is controlled. A carrying gas supply line 56 is connected to the source material tank 48 to supply a pressurized inert gas, such as Ar gas, into the source material tank 48 to supply the liquid material 46 by pressure from the source material tank 48. A plurality of shutoff valves 54 are placed in the source material supply line 49 to stop the flow of the liquid material 46 as the need arises.

A carrier gas supply line 62 is connected to the vaporizer 52. A flow controller 58, such as a mass flow controller, and a shutoff valve 60 are placed in the carrier gas supply line 62. An inert gas, such as Ar gas, as a carrier gas is supplied to the vaporizer 52 as the need arises. The source gas generated by vaporizing the liquid material by the vaporizer 52 is supplied together with the carrier gas to the shower head 24. Preferably, a tape heater is wound round a part of the source material supply line 49 extending on the downstream side of the vaporizer 52 to prevent the reliquefaction of the source gas.

The second source gas supply means 42 includes a material tank 66 containing a solid material 64 containing the second metal as the base material. The second metal is Cu (copper) and the solid material 64 is Cu(hfac)₂. The material tank 66 is heated by a heater or the like to sublimate the solid material 64. The material tank 66 is connected to the gas inlet port 24B of the shower head 24 by a material supply line 68. A flow controller 70 placed in the material supply line 68. The flow of the solid material 64 is controlled by the flow controller 70. A gas supply line 74 is connected to the material supply line 68 to supply an inert gas, such as Ar gas, as a carrier gas to the material supply line 68. Ar gas carries a source gas produced by sublimating the solid material 64 in the material tank 66 to the shower head 24. A plurality of shutoff valves 76 are placed in the material supply line 68 to stop the flow of the source gas as the need arises. Preferably, a tape heater is wound round a part of the material supply line 68 extending on the downstream side of the material tank 66 to prevent the liquefaction of the source gas.

The reducing gas supply means 44 includes a reducing gas supply line 84 connected to the gas inlet port 24B of the shower head 24. A flow controller 86, such as a mass flow controller, and shutoff valves 88 are placed in the reducing gas supply line 84 to supply a reducing gas, such as hydrogen gas (gas containing H₂ molecules) at a regulated flow rate. A branch line provided with a flow controller 90 and shutoff valves 92 is connected to the reducing gas supply line 84. An inert gas, such as Ar gas is supplied through the branch line as the need arises. When necessary, the film forming system is provided with another inert gas supply means for supplying another inert gas, such as N₂ (nitrogen gas), the description of which will be omitted.

A control means 94, such as a computer, controls operations of the film forming system 2. The control means 94 controls the pressure in the processing vessel 4, temperature, flow rates of the gases, and operations for supplying and stopping the gases. The control means 94 includes a storage medium 96, such as a floppy disk or a flash memory, storing a program for the control means 94 to execute to carry out the foregoing control operations.

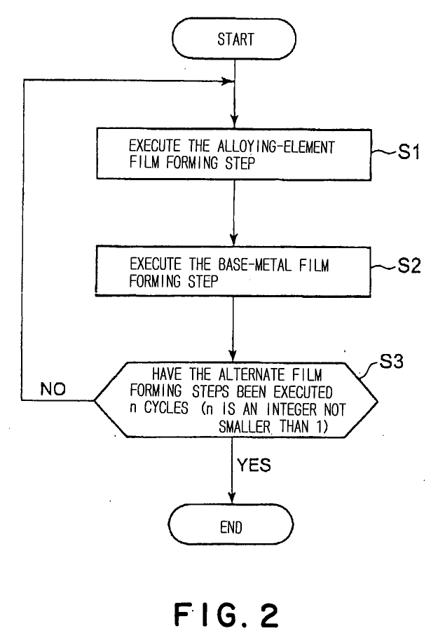

A layered thin film structure forming method for the film forming system 2 thus constructed to carry out will be described with reference to FIGS. 2 to 5.

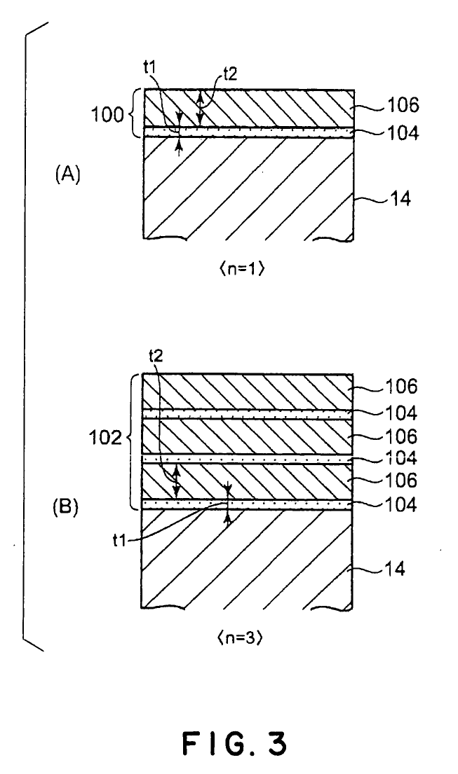

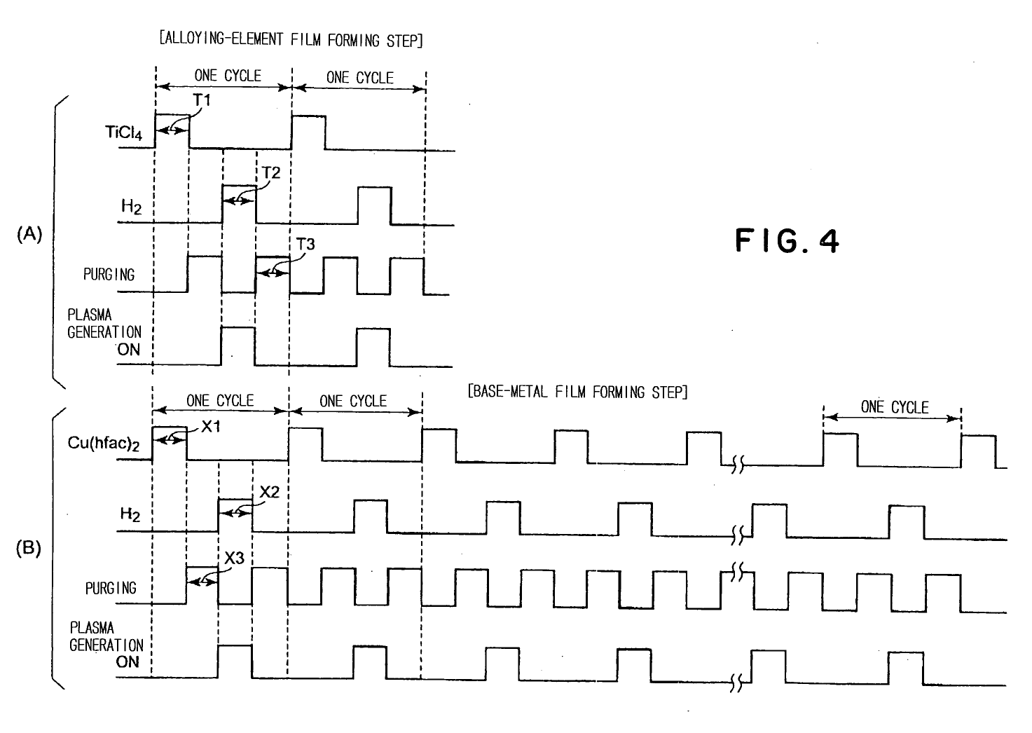

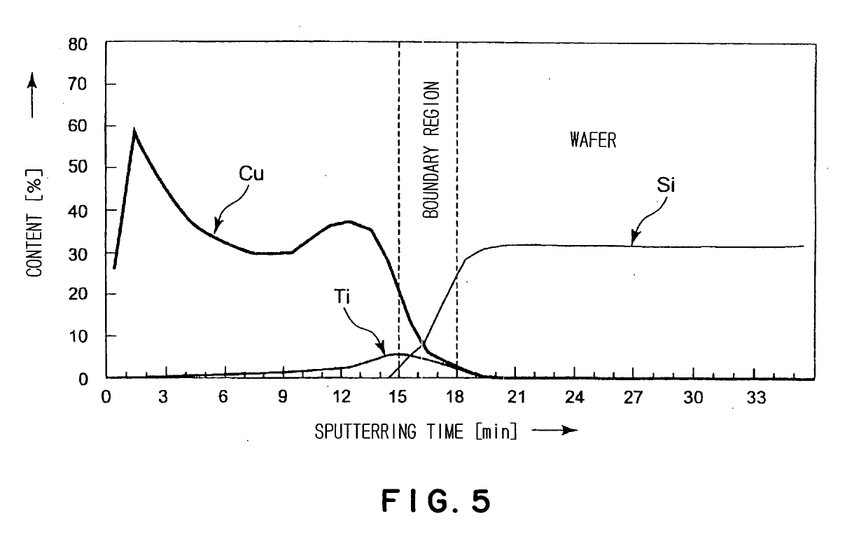

FIG. 2 is a flow chart of a layered thin film structure forming method according to the present invention, FIG. 3 is a sectional view of an example of a layered thin film structure, FIG. 4 is a time chart showing timing the supply of gases, and FIG. 5 is a profile diagram showing respective distributions of Ti content and Cu content of a surface of a wafer.

The layered thin film structure forming method of the present invention executes at least one alternate cycle of an alloying-element film forming step of forming a film of a first metal using a source gas containing the first metal, namely, an alloying element, and a reducing gas, and a base-metal film forming step of forming a base-metal film of the second metal in a thickness greater than that of the alloying-element film by using a source gas containing the second metal, namely, a base material, different from the first metal, and the reducing gas.

More concretely, as shown in FIG. 2, an alloying-element film of the first metal, namely, Ti, is formed by executing the alloying-element film forming step in step S1, and then a base metal film is formed on the alloying-element film by executing the base-metal film forming step in step S2. Those steps are carried out in the foregoing order in each cycle. The cycle is repeated necessary times, for example, n times (n is an optional integer not smaller than 1) in step S3. Those steps are executed in the same processing vessel 4, i.e., by the same film forming system.

Thus an alloy layer 100, namely, a layered thin film structure, is formed on the wafer 14 as shown in FIG. 3(A) or an alloy layer 102, namely, a layered thin film structure, is formed on the wafer 14 as shown in FIG. 3(B). A film forming operation for forming an alloying-element film 104 of Ti and a base-metal film 106 of Cu in that order on the wafer 14 is performed once or several times. The layered thin film structure shown in FIG. 3(A) is formed by carrying out the film forming operation once, namely, n=1 and has one alloying-element film 104 and one base-metal film 106. The layered thin film structure shown in FIG. 3(B) is formed by carrying out the film forming operation three times, namely, n=3, and has alternate three alloying-element films 104 and three base-metal films 106. The thickness t2 of each base-metal film 106 is greater than the thickness t1 of the alloying-element film 104. The Cu film is the base material of the alloy. The surface of the semiconductor wafer 14, namely, a ground surface on which those films are deposited, may be a surface of any suitable material, such as silicon or a barrier layer.

In FIG. 3(A) and, FIG. 3(B), the films 104 and 106 are laminated layers. Actually, thermal diffusion of the atoms of the metals forming the alloying-element film 104 and the base-metal film 106 into the adjacent films occurs because the wafer 14 is heated at a temperature, for example, between 100° C. and 400° C. during the film forming process. Thus the two kinds of metal films of the alloy layer 100 or 102, namely, a layered thin film structure, containing Cu as a base material fuse together through the thermal diffusion of atoms of the metals into the adjacent films. Consequently, Ti content of the alloy layer containing Cu as a base material is distributed naturally in a profile having a peak in the alloying-element film 104 and gradually decreasing with depth in the base-metal film 106.

Although the Ti content distribution is dependent on temperature used for film formation, the same is greatly dependent on the respective thicknesses t1 and t2 of the alloying-element film 104 and the base-metal film 106. It is desirable to form the alloying-element film 104 and the base-metal film 106 respectively in the smallest possible thicknesses t1 and t2 so that thermal diffusion of atoms can achieve an alloying-element content, namely, Ti content, that can enhance the adhesion of the layered thin film structure 100 or 102 to the underlying layer. For example, a desirable thickness of the alloying-element film 104 is between 1 and 200 Å, preferably, between 1 and 50 Å, and a desirable thickness t2 of the base-metal film 106 is between 5 and 500 Å. When the alloying-element film 104 and the base-metal film 106 are thin, laminating order of the alloying-element film 104 and the base-metal film 106 shown in FIG. 2 may be changed; the base-metal film 106 may be formed first and the alloying-element film 104 may be formed on the base-metal film 106.

Methods of forming those films will be described.

Referring to FIG. 1, the source gas containing Ti, namely, the first metal is supplied in the following manner. Liquid TiCl₄, namely, the liquid material, is supplied by pressure from the source material tank 48 of the first source gas supply means 40 at a regulated flow rate to the vaporizer 52, and TiCl₄ is vaporized by the vaporizer 52 to generate a TiCl₄ source gas. This source gas is supplied together with the carrier gas through the source material supply line 49 into the shower head 24. The source gas and the carrier gas are spouted through the shower head 24 into the processing vessel 4.

The source gas containing Cu, namely, the second metal, is supplied in the following manner. The solid material, namely, Cu(hfac)₂, contained in the material tank 66 is sublimated to produce a source gas. This source gas is supplied together with a carrier gas at a regulated flow rate by pressure through the material supply line 68 into the shower head 24. The source gas and the carrier gas are spouted through the shower head 24 into the processing vessel 4.

The reducing gas supply means 44 supplies the reducing gas, namely, a gas containing H₂ molecules, at a regulated flow rate through the reducing gas supply line 84 into the shower head 24. The reducing gas is spouted through the shower head 24 into the processing vessel 4. The evacuating system 12 is operated continuously during the film forming process to evacuate the processing vessel 4 so that the interior of the processing vessel 4 is maintained at a predetermined pressure. The heating means 22 heats the wafer 14 mounted on the stage 18 to maintain the wafer 14 at a predetermined temperature. The plasma generating means 30 supplies high-frequency power across the shower head 24 serving as the upper electrode, and the stage 18 serving as the lower electrode to generate a plasma in the processing vessel 4 to activate the gases as the need arises.

FIG. 4(A) shows timing supplying the gases for forming the Ti film, namely, the alloying-element film, in the alloying-element film forming step. The Ti film is formed one by one by an ALD (atomic layer deposition) process for forming the Ti film in an atomic thickness. TiCl₄ gas, namely, the source gas, and hydrogen gas containing H₂ molecules, namely, the reducing gas, are supplied alternately and intermittently in different periods, respectively, for an intermittent film forming process. Purging is performed to purge residual gases from the processing vessel 4 in an interval between a source gas supply period and a reducing gas supply period. The supply of all the gases may be stopped and evacuation may be continued or the supply of the source gas and the reducing gas may be stopped, evacuation may be continued and the inert gas may be supplied during a purging period.

A plasma is generated (plasma generation is ON) only during a reducing gas supply period for supplying the reducing gas, namely, hydrogen gas containing H₂ molecules, to activate hydrogen gas containing H₂ molecules. Thus reactions can be promoted even if the wafer is heated at a low temperature. Consequently, the source gas supplied into the processing vessel 4 and adhering to the surface of the wafer is reduced by the gas containing H₂ molecules and a Ti film of an atomic thickness is deposited. In the example shown in the drawing, two cycles of the film forming process are performed. The cycle of the film forming process is repeated until a film of a necessary thickness is formed. Generally, the film forming process is repeated by 1 to 10 cycles. The thickness of the film formed by one cycle of the film forming process is in the range of about 1 to about 10 Å. One TiCl₄ gas supply period T1, one hydrogen gas supply period T2 and one purging period T3 are between about 0.5 and about 5 sec, between about 0.5 and about 10 sec and between about 0.5 and about 10 sec, respectively. Process conditions are a process temperature between about 100° C. and about 400° C., and a process pressure between about 13.3 and about 1330 Pa (about 0.1 and about 10 torr).

FIG. 4(B) shows timing supplying the gases for forming the Cu film, namely, the base-metal film, in the base-metal film forming step. The Cu film is formed by one by one an ALD (atomic layer deposition) process for forming the Cu film in an atomic thickness. Cu(hfac)₂ gas, namely, the source gas, and hydrogen gas containing H₂ molecules, namely, the reducing gas, are supplied alternately and intermittently in different periods, respectively, for an intermittent film forming process. Purging is performed to purge residual gases from the processing vessel 4 in an interval between a source gas supply period and a reducing gas supply period. The supply of all the gases may be stopped and evacuation may be continued or the supply of the source gas and the reducing gas may be stopped, evacuation may be continued and the inert gas may be supplied during a purging period.

A plasma is generated (plasma generation is ON) only during a reducing gas supply period for supplying the reducing gas, namely, hydrogen gas containing H₂ molecules, to activate hydrogen gas containing H₂ molecules. Thus reactions can be promoted even if the wafer is heated at a low temperature. Consequently, the source gas supplied into the processing vessel 4 and adhering to the surface of the wafer is reduced by the hydrogen gas containing H₂ molecules and a Cu film of an atomic thickness is deposited. In the example shown in the drawing, a plurality of cycles of the film forming processes are performed. The cycle of the film forming processes is repeated until a film of a necessary thickness is formed. Generally, the film forming processes are repeated by several tens to several hundreds cycles. The thickness of the film formed by one cycle of the film forming processes is in the range of about 1 to about 2 Å. One Cu(hfac)₂ gas supply period X1, one hydrogen gas supply period X2 and one purging period X3 are between about 0.5 and about 5 sec, between about 0.5 and about 10 sec and between about 0.5 and about 10 sec, respectively. Process conditions are a process temperature between about 100° C. and about 400° C., and a process pressure between about 13.3 and about 1330 Pa (about 0.1 and about 10 torr).

A cycle of the alloying-element film forming step and the base-metal film forming step is executed once to form the layered thin film structure shown in FIG. 3(A) or three times to form the layered thin film structure shown in FIG. 3(B). As mentioned above, thermal diffusion of the atoms of the metals occurs because the wafer is heated at a temperature between about 100° C. and about 400° C. during the film forming processes. Thus the two kinds of metal films are alloyed with each other to form the alloy layer 100 or 102 as shown in FIG. 3(A) and, FIG. 3(B). The alloy layers are not limited to those having one layer of the alloying-element film 104 and one layer of the base-metal film 106 and those having alternate three layers of the alloying-element film 104 and three layers of the base-metal film 106. As mentioned above, the alloy layer may have a necessary number of layers of those component films.

The alloying-element films 104 and the base-metal films 106 in different layers of the layered thin film structure as shown in FIG. 3(B) may be formed in different thicknesses, respectively. For example, in the layered thin film structure shown in FIG. 3(B), the thicknesses of the base-metal film 106 of the first layer may be 30 Å and the thickness of the second layer may be three times of that of the base-metal film 106, 90 Å.

A layered thin film structure was thus formed and the layered thin film structure was examined. Results of examination will be described.

Element contents of a SILICON wafer and an alloy layer formed directly on a surface of the wafer were measured by XPS. FIG. 5 is a graph showing distributions of element contents with respect to a direction along the thickness of the wafer. In FIG. 5, sputtering time is measured on the horizontal axis. The surface of the wafer is removed gradually by sputtering. FIG. 5 shows the variations of the element contents with the progress of sputtering. In FIG. 5, sputtering time corresponds to a distance along the thickness of the film. FIG. 5 shows the variations of Si content, Cu content and Ti content. It was found that a boundary region between the silicon wafer and the alloy layer had a high Ti content as obvious from FIG. 5 and the satisfactory thermal diffusion of Ti occurred in the decreasing direction of the thickness to form a part having a certain Ti content.

The wafer may be subjected to an annealing process for heating the wafer at a predetermined temperature after the layered thin film structure has been formed on the wafer. The annealing process ensures satisfactory diffusion of Ti.

Since the Ti content of a local boundary region between the alloy layer and the surface of the wafer can be increased, the adhesion of the alloy layer to the underlying surface of the wafer can be increased. Ti atoms can be distributed in the entire layered thin film structure, namely, the alloy layer 100 or 102, by thermal diffusion.

Differing from the conventional film forming method using a sputtering process, the layered thin film structure forming method of the present invention forms films by an ALD process which can deposit a film in satisfactory uniform step coverage.

Although the foregoing embodiment has been described in terms of the ALD process that supplies the source gas and the reducing gas alternately and intermittently, the film forming process for the layered thin film structure forming method of the present invention to carry out is not limited to the ALD process; the film forming process may be a CVD process. The CVD process may be either of a plasma-enhanced CVD process and a thermal CVD process not using any plasma. The CVD process is a continuous film deposition process in which a source gas and a reducing gas are supplied simultaneously into a processing vessel to deposit a film continuously.

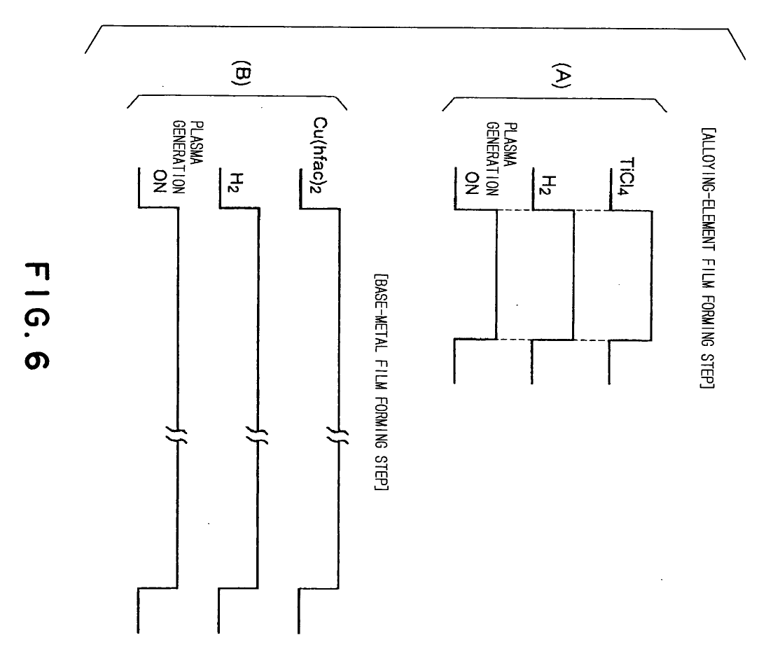

FIG. 6 is a time chart showing timing the supply of gases to form a layered thin film structure by a plasma CVD process. FIG. 6(A) shows timing supplying gases in an alloying-element film forming process. FIG. 6(B) shows timing supplying gases in a base-metal film forming process. As obvious from FIG. 6, a source gas and a reducing gas are supplied simultaneously, and a plasma is generated in synchronism with the supply of the source gas and the reducing gas. Thus a Ti film and a Cu film are formed by plasma-enhanced CVD processes, respectively. The thickness of a Cu film is greater than that of a Ti film. Therefore, a film deposition time for forming the Cu film shown in FIG. 6(B) is longer than a film deposition time for forming the Ti film shown in FIG. 6(A). For example, a film deposition time for the alloying-element film forming step is between about 10 and abut 20 sec, and a film deposition time for the base-metal film forming step is between about 200 and about 2000 sec. The CVD process forms a film at a high deposition rate, increases throughput accordingly, and improves filling property and step coverage.

The layered thin film structure may be formed by using the ALD process and the CVD process in combination. For example, the alloying-element film forming step may execute the ALD process, and the base-metal film forming step may execute the CVD process.

The alloying-metal film forming step and the base-metal film forming step do not need to be carried out in the same processing vessel, i.e., by the same film forming system as mentioned above; the wafer may be carried from one to another of a plurality of film forming devices of a clustered film forming system without exposing the wafer to the atmosphere, and the alloying-element film and the base-metal film may be formed by the different film forming devices specially assigned to forming the alloying-element film and the base-metal film, respectively.

The material containing Ti is not limited to TiCl₄ used by the foregoing embodiment; the material containing Ti may be TiF₄ (titanium tetrafluoride), TiBr₄ (titanium tetrabromide), TiI₄ (titanium tetraiodide), Ti[N(C₂H₅CH₃)₄ (TEMAT: tetrakis(ethylmethyl)aminotitanium), Ti[N(CH₃)₂]₄ (TDMAT: tetrakis(dimethyl)aminotitanium) or Ti[N(C₂H₅)₂]₄ (TDEAT: tetrakis(diethyl)aminotitanium).

The first metal is not limited to Ti used by the foregoing embodiment; the first metal may be a metal chosen from, for example, a group of metals including Ti, Sn, W, Ta, Mg, In, Al, Ag, Co, Nb, B, V and Mn.

The reducing gas is not limited to hydrogen gas containing H₂ molecules used by the foregoing embodiment; the reducing gas may be one or a mixture of some of a group of gases including H₂, NH₃, N₂, N₂H₄ (hydrazine), NH(CH₃)₂ (ethylamine), N₂H₃CH (methyl diazine) and N₂₂H₃CH₃ (methyl hydrazine).

The workpiece is not limited to the semiconductor wafer; the workpiece may be a glass substrate, a LCD substrate or the like.

1. A layered thin film structure forming method of forming a layered thin film structure by depositing a plurality of thin films on a surface of a workpiece in a processing vessel capable of being evacuated, the layered thin film structure forming method comprising the steps of:
forming an alloying-element film of a first metal by using a source gas containing the first metal as an alloying element, and a reducing gas; and
forming a base-metal film of a second metal different from the first metal in a thickness greater than that of the alloying-element film by using a source gas containing the second metal, and a reducing gas;
wherein at least one cycle of the alternate steps of forming the alloying-element film and forming the base-metal film is executed.

2. The layered thin film structure forming method according to claim 1, wherein an intermittent film forming process in which the source gas containing the first metal, and the reducing gas are supplied alternately and intermittently in different periods, respectively, into the processing vessel or a continuous film forming process in which the source gas containing the first metal, and the reducing gas are supplied simultaneously into the processing vessel is carried out in the step of forming the alloying-element film.

3. The layered thin film structure forming method according to claim 1, wherein an intermittent film forming process in which the source gas containing the second metal, and the reducing gas are supplied alternately and intermittently at different periods, respectively, into the processing vessel or a continuous film forming process in which the source gas containing the second metal, and the reducing gas are supplied simultaneously into the processing vessel is carried out in the step of forming the base-metal film.

4. The layered thin film structure forming method according to any one of claims 1 to 3, wherein the workpiece is subjected to an annealing process for heating the workpiece at a predetermined temperature after completing one cycle of the alternate steps of forming an alloying-element film of a first metal and forming a base-metal film of a second metal.

5. The layered thin film structure forming method according to any one of claims 1 to 3, wherein the step of forming an alloying-element film and the step of forming a base-metal film are executed in the same processing vessel.

6. The layered thin film structure forming method according to any one of claims 1 to 3, wherein the step of forming an alloying-element film and the step of forming a base-metal film are executed alternately in different processing vessels, respectively.

7. The layered thin film structure forming method according to any one of claims 1 to 3, wherein the alloying-element film has a thickness between 1 and 200 Å, and the base-metal film has a thickness between 5 and 500 Å.

8. The layered thin film structure forming method according to any one of claims 1 to 3, wherein the first metal is one of a group of metals including Ti, Sn, W, Ta, Mg, In, Al, Ag, Co, Nb, B, V and Mn.

9. The layered thin film structure forming method according to any one of claims 1 to 3, wherein the second metal is one of a group of metals including Cu, Ag, Au and W.

10. The layered thin film structure forming method according to any one of claims 1 to 3, wherein the reducing gas is one or a mixture of some of H₂, NH₃, N₂, N₂H₄ (hydrazine), NH(CH₃)₂ (ethylamine), N₂H₃CH (methyl diazine)or N₂H₃CH₃ (methyl hydrazine).

11. A layered thin film structure formed on a surface of a workpiece, said layered thin film structure comprising: at least one alloying-element film of a first metal formed by using a source gas containing the first metal as an alloying element, and a reducing gas; and
at least one base-metal film of a second metal having a thickness greater than that of the alloying-element film and formed by using a source gas containing the second metal different form the first metal, and a reducing gas;
wherein the alloying-element film and the base-metal film are laminated in alternate layers.

12. The layered thin film structure according to claim 11, wherein the alloying-element film has a thickness between 1 and 200 Å, and the base-metal film has a thickness between 5 and 500 Å.

13. A film forming system for depositing thin films on a surface of a workpiece, said film forming system comprising:
a processing vessel capable of being evacuated;
a stage for supporting the workpiece thereon;
a heating means for heating the workpiece;
a gas introducing means for introducing gases into the processing vessel;
a first source gas supply means for supplying a source gas containing a first metal as an alloying element to the gas introducing means;
a second gas supply means for supplying a source gas containing a second metal as a base material to the gas introducing means;
a reducing gas supply means for supplying a reducing gas to the gas introducing means; and
a control means for controlling film forming operations such that at least one alloying-element film of the first metal and at least one base-metal film of the second metal are formed in alternate layers.

14. The film forming system according to claim 13, further comprising a plasma generating means for generating a plasma in the processing vessel.

15. A storage medium storing a program for controlling a film forming system for forming a layered thin film structure by depositing a plurality of thin films on a surface of a workpiece in a processing vessel capable of being evacuated such that the film forming system executes at least one cycle of alternate steps of forming an alloying-element film of a first metal by using a source gas containing the first metal as an alloying element and, a reducing gas, and forming a base-metal film of a second metal in a thickness greater than that of the alloying-element film by using a source gas containing the second metal, and a reducing gas.

16. The layered thin film structure forming method according to claim 1, wherein at least two cycles of the alternate steps of forming the alloying-element film and forming the base-metal film is executed.

17. The layered thin film structure forming method according to claim 1, wherein the intermittent film forming process is selected from among the intermittent film forming process and the continuous film forming process, and the intermittent film forming process is executed.

18. The layered thin film structure according to claim 11, wherein at least two alloying-element films and at least two base-metal films are formed in alternate layers.

19. The storage medium according to claim 15, wherein the program for controlling a film forming system includes instructions for controlling the film forming system so as to execute at least two cycles each of the alternate steps of forming the alloying-element film and forming the base-metal film are executed.
